(19) United States
(12) Patent Application Publication
(10) Pub. No.: US 2016/0348239 A1
(43) Pub. Date: Dec. 1, 2016

(54) Heat Beam Film-Forming Apparatus

(71) Applicant: PHILTECH, Inc., Tokyo (JP)

(72) Inventors: Yuji FURUMURA, Kanagawa (JP); Noriyoshi SHIMIZU, Tokyo (JP); Shinji NISHIHARA, Tokyo (JP)

(21) Appl. No.: 14/854,709

(22) Filed: Sep. 15, 2015

(30) Foreign Application Priority Data
Jun. 1, 2015 (JP) 2015-111730

(51) Int. Cl. C23C 16/452; C23C 16/458; C23C 16/40; C23C 16/455

(52) U.S. Cl. CPC C23C 16/452; C23C 16/455; C23C 16/4582; C23C 16/401

(57) ABSTRACT

To form a film by generating molecular species which can react at a low temperature, especially, 100° C. or less at which a substrate is not deformed or altered. In a heat beam heating device which instantaneously heats a source gas to a high temperature to cause the source gas to collide with a metal wall including a catalytic function, activated molecular species are generated by a nonequilibrium reaction, sprayed on, and brought into contact with a substrate to form a film.

### BACKGROUND

Field of the Invention

The present invention relates to a heat beam film-forming apparatus that guides a gas generated by changing a source gas through a component that instantaneously heats the gas to a temperature higher than a temperature of a substrate to a substrate surface to form a film.

Description of Related Art

In general, most of chemical bond energies of molecules in a gas are 3 eV or more. Even though the gas is merely heated to a high temperature, the molecules are not decomposed. However, when a gas heated to a high temperature is caused to vertically collide with a metal containing an element having a catalytic effect, the gas molecules easily react. When chemically reactive gas species are heated and caused to collide with a catalyst, the gas species react to make it possible to generate a gas including molecular species different from those of the original gas or having a form different from that of the original gas (to be referred to as a catalyst collision reaction hereinafter). For example, when, in a vessel containing a ruthenium catalyst, a gas obtained by instantaneously heating methane and water vapor is caused to collide with the ruthenium catalyst, the reaction proceeds to generate hydrogen H₂, carbon dioxide CO₂, and carbon monoxide CO. This reaction is one example of a catalyst collision reaction (for example, see Japanese Patent Application No. 2014-211750). At this time, although water is heated to be vapored, the temperature does not only simply become high, the structure of the water is considered to be changed from polymers (clusters of water) obtained by polymerizing molecules into monomers. The generated monomer gas is estimated to be changed in chemical characteristic and to have an active chemical characteristic different from that of normal water.

In order to industrially use the catalyst collision reaction, a device for instantaneously heating a gas and a low-price compact heating device for causing a gas to collide with a catalyst are required.

Gas heating devices which satisfy the requests are devices described in Japanese Patent Application No. 2012-107128, Japanese Patent Application No. 2012-203119, Japanese Patent Application No. 2013-237211, Japanese Patent Application No. 2013-197594, and Japanese Patent No. 5105620. The instantaneously-heating devices described in the patent documents are called heat beam heating devices here. This principle is to cause a gas to collide with a high-temperature wall at a high speed to efficiently perform heat exchange between the wall and the gas.

In order to clarify an explanation of the principle, a main structural diagram of a heat exchanger of the instantaneously-heating device described in Japanese Patent No. 5105620 is cited and shown in FIG. 4. According to the patented document, the speed of a gas is increased in a narrow gas flow path formed on a surface of a heat exchange substrate material, and the gas is caused to vertically collide with a flow path wall. Since this flow path wall is electrically heated, heat exchange is caused by this collision. In addition, since a heat beam heating device described in Japanese Patent No. 5105620 has the above-mentioned structure configured by a plurality of stages, the gas can be efficiently instantaneously heated.

Japanese Patent No. 5105620 further discloses an invention of a film-forming apparatus that heats a plurality of gases with the heat beam heating device and grows, on a glass or plastic substrate kept at a temperature lower than the heating temperature, a material which has not been able to be formerly grown without heating the substrate to a high temperature.

The invention of Japanese Patent No. 5105620 further discloses an invention in which a carrier gas and a source gas having a depositional property, which are produced by the heat beam heating device, are guided and sprayed on a substrate surface while being kept at a low temperature to form a film.

The invention of Japanese Patent No. 5105620 discloses an invention of a film-forming apparatus in which the same devices are arrayed on the substrate surface to spray different gas species.

### SUMMARY OF INVENTION

However, the invention of Japanese Patent No. 5105620 has an issue in which radiant heat disadvantageously deforms plastic or glass because a distance between the substrate and a high-temperature heat exchange component made of carbon is short. For this reason, in order to handle a plastic substrate, an active reactant gas must be chemically produced from a source gas at a lower temperature and guided to the substrate.

Thus, the present invention has been made in consideration of the above issue, and has as its object to fabricate the heat beam heating device by using a metal expected to have a catalytic function, to cause a source gas which can be changed into chemically active molecular species to collide and be incident with/on the metal surface, to apply a generated desired gas to a film-forming apparatus, and to form a material thin film which has not been able to be formerly formed only in a high-temperature environment on a substrate surface kept at a temperature lower than a heating temperature of the heat beam heating device.

The present invention provides the following items to address the above issue.

(1) One or more embodiments of the present invention provides a heat beam film-forming apparatus including a source gas instantaneously-heating mechanism having a flow path structure which causes a source gas heated to a high temperature to repeatedly collide at a high speed with a metal material containing an element having a catalytic function, and a substrate supported at a temperature lower than a temperature of the source gas instantaneously-heating mechanism, wherein a generated gas generated through the source gas instantaneously-heating mechanism is sprayed and brought into contact with the substrate to form a film.

(2) One or more embodiments of the present invention provide a heat beam film-forming apparatus wherein, in the heat beam film-forming apparatus according to (1), a surface of a flow path of the source gas instantaneously-heating mechanism is made of a metal containing at least one of elements including ruthenium, nickel, platinum, iron, chromium, aluminum, and tantalum.

(3) One or more embodiments of the present invention provide a heat beam film-forming apparatus wherein, in the heat beam film-forming apparatus according to (1), the source gas instantaneously-heating mechanism includes a plurality of source gas instantaneously-heating mechanisms.

(4) One or more embodiments of the present invention provide a heat beam film-forming apparatus wherein, in the heat beam film-forming apparatus according to (1), the source gas is water, a hydrogen carbide such as methane, an organic metal gas containing aluminum or one metal element selected from hafnium, gallium, zinc, titanium, silicon, magnesium, and indium, an inert gas containing nitrogen or argon, a reducing gas such as hydrogen or ammonia, or a gas mixture thereof.

(5) One or more embodiments of the present invention provide a heat beam film-forming apparatus wherein, in the heat beam film-forming apparatus according to (1), a heating temperature of the source gas instantaneously-heating apparatus ranges from 500° C. to 900° C.

(6) One or more embodiments of the present invention provide a heat beam film-forming apparatus wherein, in the heat beam film-forming apparatus according to (1), the substrate is glass, a silicon wafer, plastic, or carbon.

(7) One or more embodiments of the present invention provide a heat beam film-forming apparatus wherein, in the heat beam film-forming apparatus according to (1), the substrate moves.

(8) One or more embodiments of the present invention provide a heat beam film-forming apparatus wherein, in the heat beam film-forming apparatus according to (1), the substrate is a substrate on which an organic EL device, a liquid crystal device, a solar battery cell, or a photoresist pattern is formed.

According to one or more embodiments of the invention of claim 1 or claim 2, the source gas heated to a high temperature is changed to generate a chemically active molecular species, a beam of the molecular species is sprayed on and brought into contact with a substrate surface to make it possible to form a thin film on a surface of the substrate kept at a temperature lower than a temperature of the source gas instantaneously-heating mechanism.

Since the temperature of the source gas instantaneously-heating mechanism can be arbitrarily set, a thin film can be grown independently of the temperature of the substrate. When the type of the source gas and a catalytic metal element of the flow path therefor are selected, the temperature of the source gas instantaneously-heating mechanism depending on desired generated molecular species. For example, when the desired molecular species are not degradation species, the temperature can be designed not to be high. More specifically, when water is heated at a temperature higher than 100° C., the state of the water is considered not to be a cluster state but to be changed into molecular species of monomers. For this reason, the active oxidized molecular species can be involved in a film-forming reaction.

According to one or more embodiments of the invention of claim 3 or claim 4, a plurality of active generated molecular species are combined to each other to make it possible to contribute to a film-forming reaction. In film formation of a compound, for example, when generated molecular species of a material containing a metal element and generated molecular species containing an element of an oxidant are sprayed on the substrate surface, a reaction easily occurs to make it possible to achieve the film formation at a lower temperature.

For example, it is known that a material containing a silicon element or an element such as aluminum, zirconium, or magnesium is oxidized to generate high energy and strongly reacts with a material of water containing oxygen atoms. As a source gas related to oxidation and reduction, typically, an organic metal gas containing water, a hydrogen carbide, or one metal element selected from aluminum, hafnium, gallium, zinc, titanium, silicon, magnesium, and indium, a reducing gas such as hydrogen or ammonia, and a gas mixture thereof are known. Combinations of these source gases can be freely designed. Active species generated from the source gas are desired to be diluted in a substrate surface atmosphere, a heated generated gas of an inert gas such as nitrogen or argon can also be used as a third spray gas. The source gas can also be conveyed and sprayed with a carrier gas of a high-temperature heated inert gas.

According to one or more embodiments of the invention of claim 5, the heating temperature can be selected from a range from 100° C. to 900° C. Since water is vaporized at 100° C., it is understood that water serving as an oxidant is a monomer when the source gas instantaneously-heating mechanism has a temperature of 100° C. or more. On the other hand, stainless steel serving as a metal material containing an element of a catalyst such as nickel or iron is oxidized by an oxidant such as a halide gas or water at 500° C. or more or becomes brittle with a reducing reaction caused by a gas such as hydrogen or ammonia. For this reason, in the source gas instantaneously-heating mechanism to a metal material expected to have a catalytic function, heating is limited to heating at a relatively low temperature. However, a ceramics material such as quartz, silicon carbide, or alumina is used to fabricate the source gas instantaneously-heating mechanism to make it possible to fabricate a heat beam heating device that can perform heating up to a temperature of about 900° C.

According to one or more embodiments of the invention of claim. 6, the substrate can be selected from glass, silicon wafer, plastic, and carbon. More specifically, since the substrate is kept at a temperature which the substrate can withstand to make it possible to form a film, a material can be selected as the substrate. For example, when glass is used, the substrate can be kept at 600° C. or less. When plastic, for example, polycarbonate is used, the substrate can be kept at 200° C. When PET is used, the substrate can be kept at 80° C. or less. Although silicon or carbon is a heat-resistant material, an issue of warpage or an issue of contamination may disadvantageously increase the cost of a film-forming apparatus. For this reason, actually, the substrate is desirably kept at a temperature close to room temperature.

According to one or more embodiments of the invention of claim 7, the substrate can be relatively moved with reference to spraying of a generated gas. When a place on which a generated gas of a source gas A is sprayed and a place on which a generated gas of a source gas B is sprayed are represented by a and b, respectively, sets of ab are arranged in n stages, i.e., ab, ab, . . . , ab. When the substrate moves through the sprayed places, a compound AB of the generated gases of the source gas A and the source gas B can be continuously formed as a film on a substrate surface. When the substrate has a film-like shape, the compound AB can be continuously formed as a film on the film.

According to one or more embodiments of the invention of claim 8, a film can be formed on the substrate on which an organic EL device, a liquid crystal device, a solar battery, or a photoresist pattern is formed. More specifically, a display device typified by the organic EL is deteriorated by oxidization or moisture absorption. This prevents the display device that the service life is guaranteed from being practically used. For this reason, while a large-area substrate is kept at a low temperature, a thin film of a moisture-proof material cannot be formed on the surface of the substrate on which the device is formed. Thus, at present, a vacuum sputtering method for a silicon oxide film is only a method. However, the manufacturing cost of the vacuum sputtering method is high to prevent a large-size EL display from being practically used. The long-term reliability of the solar battery cannot be secured without increasing the manufacturing cost. However, according to the invention of claim 8, these manufacturing costs can be reduced.

A silicon oxide film or the like serving as a mask material having resistance to dry etching is grown on a photoresist pattern. However, this growing step is an expensive step because a plasma CVD method is used. However, in the present invention, since a film-forming method which does not use plasma is employed, an inexpensive step can be achieved.

### BRIEF DESCRIPTION OF DRAWINGS

FIG. 1 is a pattern diagram of a basic structure of a heat beam film-forming apparatus.

FIG. 2 is a pattern diagram of a film-forming apparatus in which heat beam film-forming apparatuses are arranged in multiple stages.

FIG. 3 is a pattern diagram of a heat beam film-forming apparatus using a continuous film as a substrate.

FIGS. 4A, 4B, 4C and 4D are cited diagrams in Japanese Patent No. 5105620, and is a pattern diagram of a main part showing a principle of a heat exchange mechanism.

### DETAILED DESCRIPTION

### Embodiment

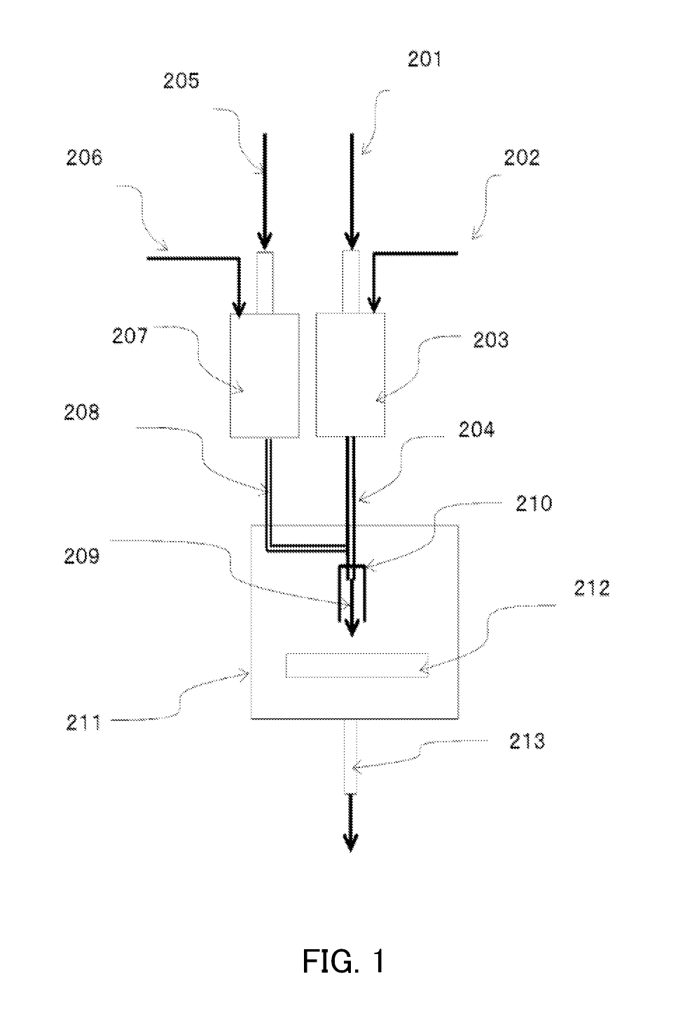

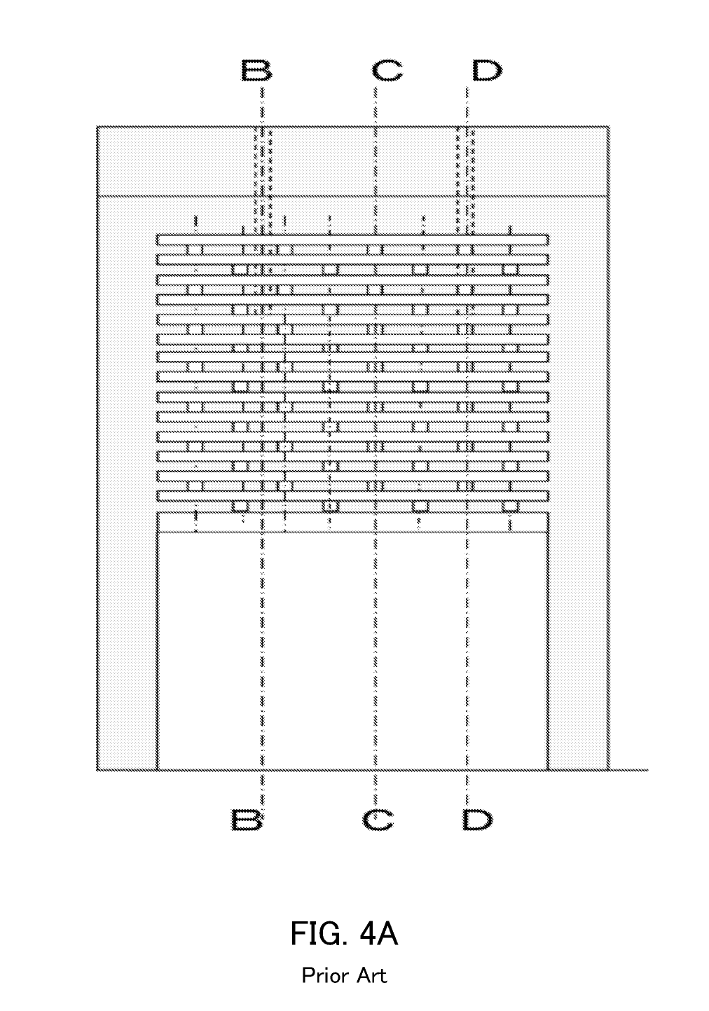

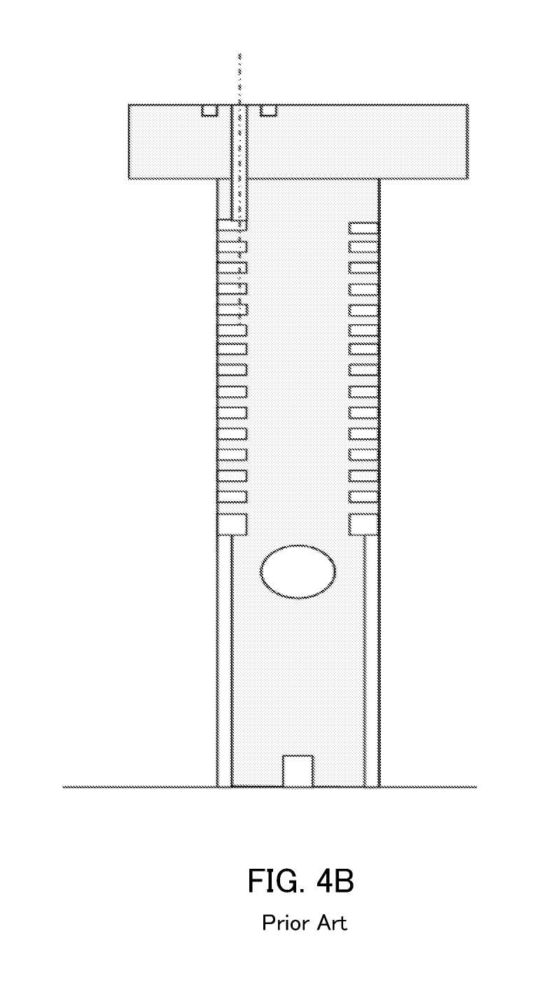

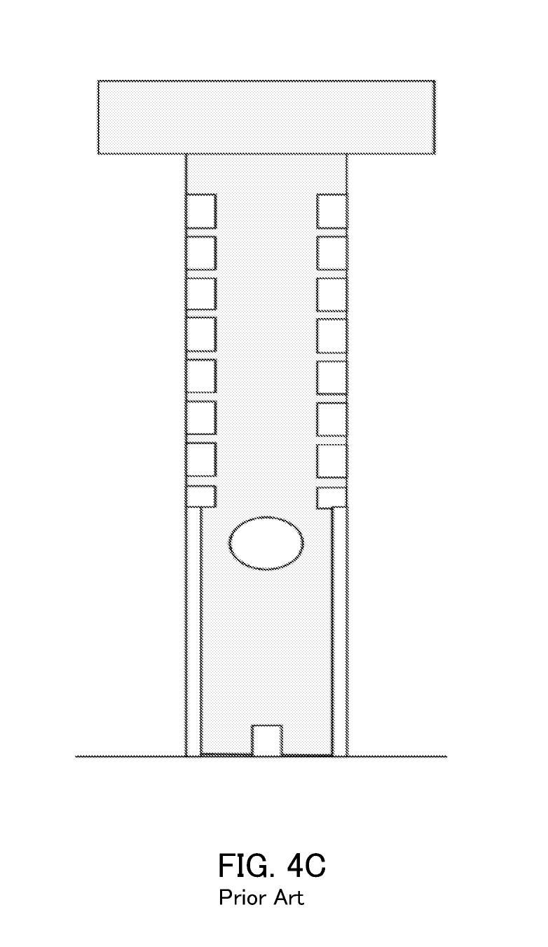

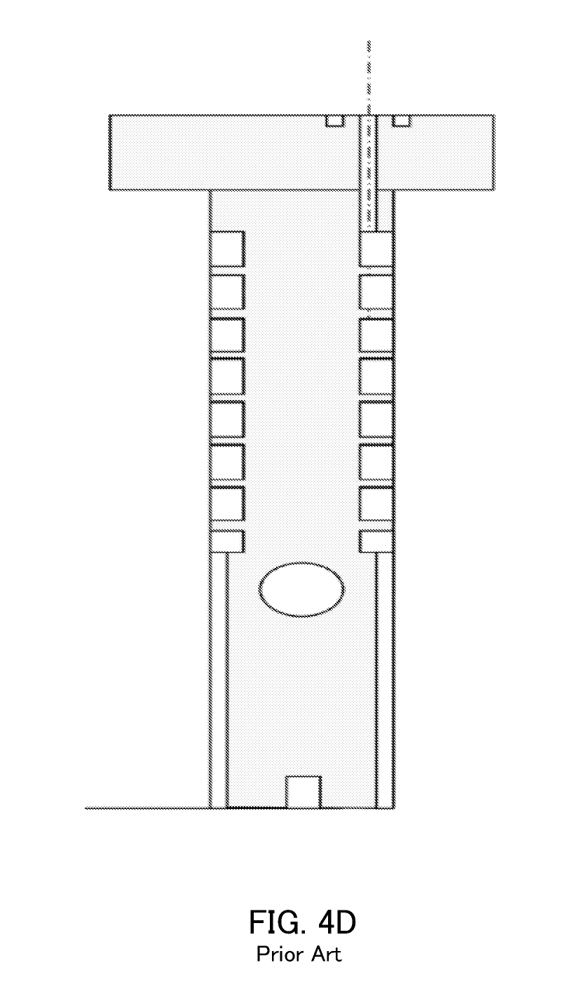

An embodiment of the present invention will be described below with reference to FIG. 1 to FIG. 4. A film-forming apparatus according to the present invention is an apparatus which makes it possible to form a film even though a substrate is supported at a low temperature within the range of room temperature to about 100° C.

A pattern diagram of a basic structure of a heat beam film-forming apparatus according to the present invention is shown in FIG. 1. A carrier gas 201 made of nitrogen is heated by a heat beam heating device 1 (203) which uses, as a flow path material, stainless steel containing nickel, iron, and chromium having a catalytic function as main components. A heated generated gas reaches a guide 210 through a generated gas transport pipe 204.

Similarly, a source gas 205 is heated by a heat beam heating device 2 (207), and a heated generated gas is guided to the guide 210 through a transport pipe 208. A generated gas 209 coming from the guide 210 is brought into contact with a substrate 212 disposed in a film-forming chamber 211, which is kept at a temperature lower than a temperature of a heat beam heating device and exhausted from an exhaust port 213. A film depending on the generated gas is formed on the substrate 212. The source gas can be freely programmed such that gases of two or more types are introduced in according to a time program. A program for the temperature of the heat beam heating device can be freely designed.

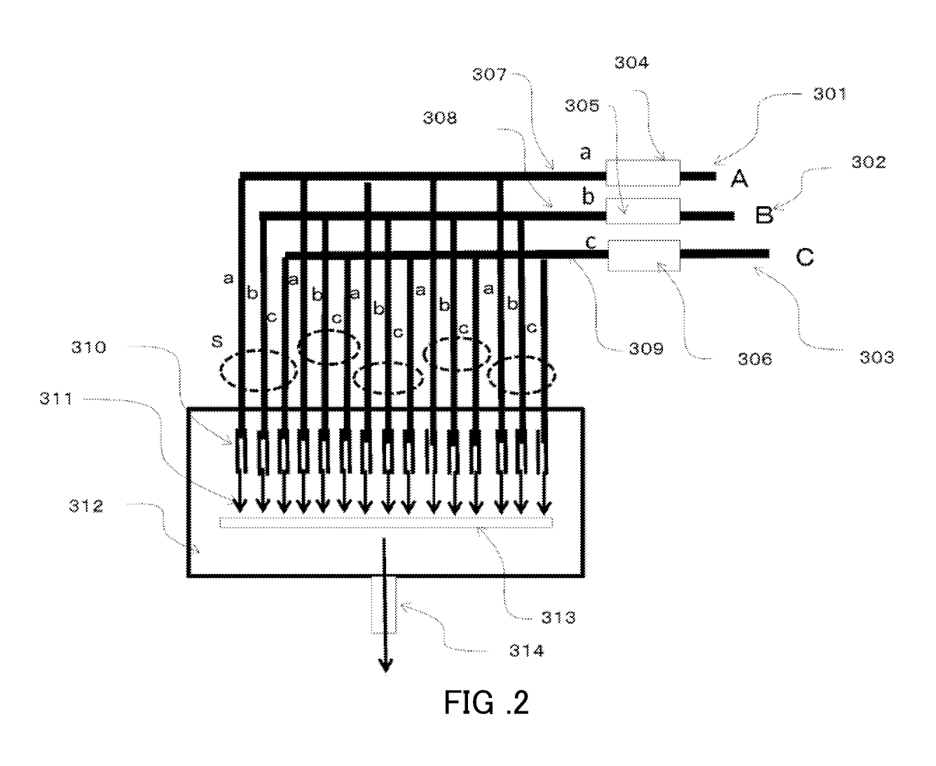

A structure of the heat beam film-forming apparatus will be described below with reference to FIG. 2.

The heat beam film-forming apparatus according to the embodiment is a film-forming apparatus in which heat beam film-forming apparatuses are arranged in multiple stages.

Source gases A, B, and C (301, 302, and 303) are heated by heat beam heating devices 304, 305, and 306 to generate generated gases a, b, and c (307, 308, and 309). Sets of the generated gases a, b, and c are distributed and arranged as sets S of a plurality of generated gases. In the case in this drawing, five sets are arranged as the sets S. The number of sets S can be freely designed depending on the size of the substrate. A generated gas 311 is sprayed on a substrate 313 supported and placed in a film-forming chamber 312 through a guide 310, and exhausted from an exhaust port 314. The source gases A, B, and C, heating temperatures, and flow rates can be freely designed, and the source gases A, B, and C can be introduced in according to time programming. The shape of the guide 310 and the arrangement of the sets S can be freely designed depending on the shape of a substrate or the number of substrates. The shape of the guide may be a slit-like shape, a pipe-like shape, or a ring-like shape. The sets may be arranged in an in-line form or a ring-like form, or may be discretely arranged.

In the heat beam film-forming apparatus according to the embodiment, gas can be freely selected depending on the types of films to be formed. A heating temperature of a gas which changes by being merely heated may be designed depending on the temperature at which the gas changes. Some liquid sources configuring polymers change into monomers depending on heating temperatures. When a gas obtained by mixing an oxidizing or reducing gas with a carrier gas is used, a chemical reaction may easily occur.

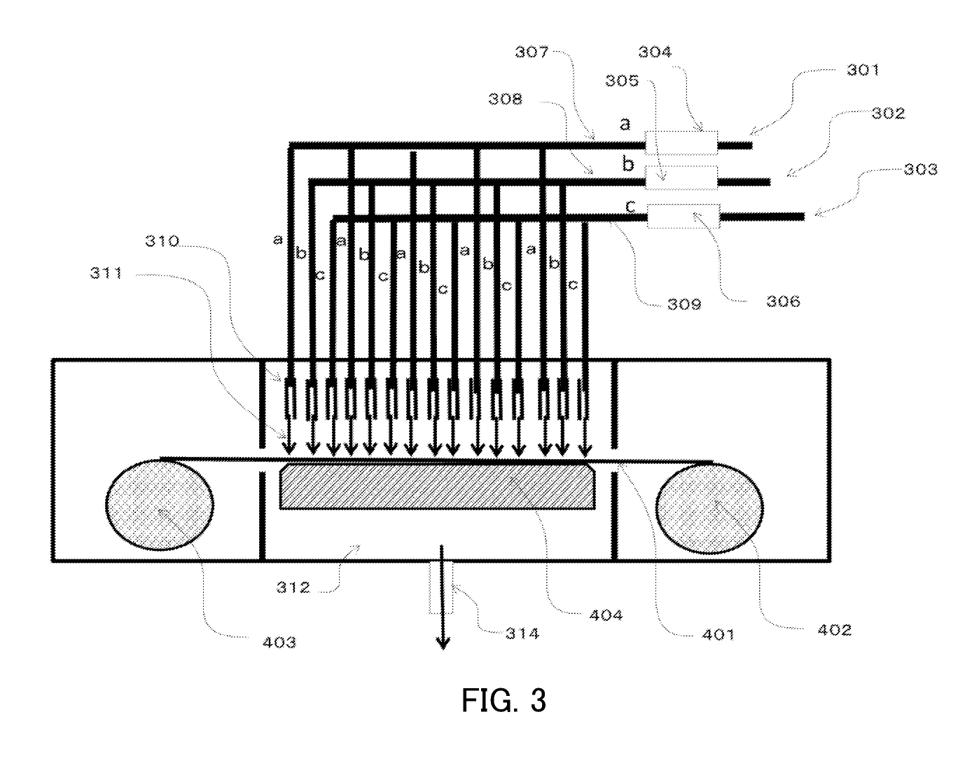

FIG. 3 shows a pattern diagram of a heat beam film-forming apparatus using a continuous film as a substrate. According to the drawing, a film 401 is supplied from a film supply drum 402. The film 401 passes over a film support table 404 and collected by a film rewinding drum 403. The sets S of the generated gases a, b, and c are arranged on the film 401 in multiple stages to form a film. The number of sets S can be freely designed depending on a desired film thickness.

### First Example

An example for checking the performance of an applied heat beam cylinder will be described first.

Steam preliminarily heated to 130° C. or more and a source methane gas were introduced into the heat beam cylinder and further heated. The temperature of the gas in the heat beam cylinder at this time was set to 540° C. The heat beam cylinder has a maximum input power of 1500 W, and increases the temperature to up to 1000° C. Ruthenium-supported alumina columnar particles were put in a ⅜-inch pipe arranged at the outlet of the cylinder, and an argon gas is used as a carrier gas.

In order to cool the generated gas, a cooling mechanism and a water collecting mechanism were connected to a generated gas outlet. When the components of the cooled generated gas were analyzed, it was confirmed that about 30% of methane changed to generate hydrogen. Other components were carbon dioxide and carbon monoxide. All the generated gas except for argon had a carbon monoxide concentration of 0.1% or less. According to the example, it was considered that a heated generated gas of water put in the heat beam cylinder was active and efficiently reacted with methane serving as a source gas to generate hydrogen. The above operation is an experiment for checking the basic performance of gas generation of the heat beam cylinder. Note that, about the heat beam cylinder, see the Internet <URL: http://www.philtech.co.jp/>.

In the first example, the reaction is accelerated by using the ruthenium catalyst. However, a predetermined catalytic effect can be expected when other materials such as nickel, platinum, iron, chromium, aluminum are used as a catalyst, although those effects are different from that of ruthenium. Since stainless steel is a metal containing nickel, a commercial heat beam cylinder fabricated by stainless steel is expected not only to perform heating but also to obtain a catalytic effect. For this reason, in the following examples, the stainless steel is used without adding a special catalyst. According to the example, water is preliminarily heated to change from a cluster state into a monomer state to make it possible to considerably improve the reactivity.

### Second Example

A film was formed by the configuration shown in the basic pattern diagram in FIG. 1. As a source gas containing silicon as an element, Tetra Ethyl Ortho Silicate (Si(OC₂H₅)₄: abbreviated as TEOS) was used. As a source gas of an oxidant, water in a cluster state was selected. TEOS and water are liquid materials. TEOS and water were bubbled with argon gas, vaporized, and used. Since the materials are liquid, they were transported with a nitrogen carrier gas preliminarily heated with the heat beam cylinder at 150° C. to prevent those liquefaction in the middle of a transport path, and the materials are used as source gases. The gases were heated to 300° C. by the re-heating heat beam cylinder attached in a reduced-pressure reaction chamber, guided onto a silicon wafer substrate of room temperature which is placed in the reduced-pressure reaction chamber, and brought into contact with the wafer alternately.

Since a source gas instantaneously-heating mechanism unit of the heat beam cylinder is fabricated by SUS, the source gas instantaneously-heating mechanism unit contains nickel, iron, and chromium which can be expected to have a catalytic effect. The source gas TEOS heated at this temperature is partially changes, and may be in an excitation state. The water serving as the material is vaporized at 100° C. or more. In the range of 100° C. to 500° C., the state can be estimated not to be in a cluster state but to be a molecular state of monomers.

In this example, the source gases are heated at 300° C. However, since a distance from the heat beam cylinder to the wafer serving as a substrate is sufficiently long in consideration of the SUS pipe, the length of the guide, and distances to the guide and the substrate, a generated gas radiates heat on the wafer and has a state having a temperature close to room temperature. When a film formed on the wafer was analyzed, it could be confirmed that the oxide film was grown. Thus, in the example, it could be confirmed that a silicon oxide film could be grown at room temperature without heating a substrate.

A thesis in which TEOS and water which are the same materials as those in the example are brought into contact with a wafer alternately at set time intervals has been already published (M. Hatanaka, Y. Furumura et al., “Plasma-CVD realizing dielectrics having a smooth surface” VMIC proceedings (1991)). In this example, as the temperature of the substrate wafer, temperatures of 200° C. to 300° C. were required. The first example, this configuration was achieved at room temperature.

Other combinations of gases to be heated and generated for film formation may be conceived. In combinations with water, as candidates of depositional source gases which can be expected to forma film except for TEOS, organic compounds (organic metals) of metals (for example, silicon, titanium, gallium, zinc, indium, aluminum, and hafnium) and those halides are given. Although a temperature range becomes high, as an application, in addition to an organic compound of gallium, a gas of a gallium chloride can be used. The gallium chloride and ammonia are brought into contact with the substrate to make it possible to grow GaN crystal. As a carrier gas, in addition to nitrogen serving as an inert gas, an argon gas is used. As a source gas which can react with an organic metal gas, not only water but also ammonia and hydrogen having reducing properties are given.

### Third Example

The present invention is suitable for an application in which a substrate wafer serving as a substrate is kept at a low temperature and a high-temperature source gas is transported to the surface of the substrate wafer and brought into contact with the semiconductor wafer to grow a crystal film. As an example of the application, each of Japanese Unexamined Patent Publication No. 2014-53477 and Japanese Patent Application No. 2015-00671 discloses a technique that reacts solid-state gallium with chloride to generate a gallium chloride, transports the gallium chloride at a high temperature, and reacts the gallium chloride with ammonia on the substrate to grow a gallium nitride (GaN) film. These techniques are characterized in that a high-temperature gallium chloride gas serving as a gas containing the gallium element is generated from solid-state gallium.

In the example, an organic metal gas (TMS: trimethyl gallium) was bubbled and vaporized, the resultant gas was heated by a carrier gas preliminarily heated by a heat beam cylinder to have a temperature of 950° C., and a high-temperature source gas was generated and transported. In addition to the vaporized TMS, ammonia was heated as a source gas by hydrogen serving as a high-temperature carrier gas and transported to the guide. A 2° off angle C-plane sapphire substrate was placed under the guide and heated to 500° C. The TMG and the ammonia were not simultaneously supplied but alternately supplied to be in contact with the substrate surface. As a result, the film was grown even though the heating temperature of the substrate was 500° C. When the film was analyzed, it was confirmed by X-ray diffraction that the film was made of crystal and was a gallium nitride (GaN) crystal film according to a grating constant. Thus, when the example is applied, the GaN crystal film can be grown without heating the substrate to a high temperature.

When, for example, a metal oxide film can be formed without heating a substrate, the technique can be applied to a protecting film for an organic EL substrate, a protecting film for a liquid crystal device, and a protecting film for a solar battery. An etching mask film can be formed on a silicon wafer as a substrate, having poor heat resistant photoresist pattern attached thereto. When a ceramics protecting film having a high hardness can be formed, a film can also be widely used as a protecting film for protecting the surface of glass or plastic from scratching. Furthermore, when titanium oxide film which is ceramics is added to constructional large-scale window glass by using organic titanium and water as a source gas, dust adhering to windows of tall buildings can be prevented.

The embodiment of the present invention has been described in detail with reference to the accompanying drawings. However, the concrete configuration of the invention is not limited to the embodiment, and includes a design or the like without departing from the spirit and scope of the invention.

### REFERENCE SIGNS LIST

201: carrier gas
202: electric power
203: heat beam heating device 1
204: transport pipe
205: source gas
206: electric power
207: heat beam heating device 2
208: transport pipe
209: generated gas
210: guide
211: film-forming chamber
212: substrate
213: exhaust port
301: source gas A
302: source gas B
303: source gas C
304: heat beam heating device
305: heat beam heating device
306: heat beam heating device
307: generated gas a of source gas A
308: generated gas b of source gas B
309: generated gas c of source gas C
S: set of generated gases
310: guide
311: generated gas
312: film-forming chamber
313: substrate
314: exhaust port
401: film
402: film supply drum
403: film rewinding drum
404: film support table

What is claimed is:

1. A heat beam film-forming apparatus comprising:
a source gas instantaneously-heating mechanism including a flow path structure which causes a source gas heated to a high temperature to repeatedly collide at a high speed with a metal material containing an element including a catalytic function; and
a substrate supported at a temperature lower than a temperature of the source gas instantaneously-heating mechanism, wherein
a generated gas generated through the source gas instantaneously-heating mechanism is sprayed and brought into contact with the substrate to form a film.

2. The heat beam film-forming apparatus according to claim 1, wherein
a surface of a flow path of the source gas instantaneously-heating mechanism is made of a metal containing at least one of elements including ruthenium, nickel, platinum, iron, chromium, aluminum, and tantalum.

3. The heat beam film-forming apparatus according to claim 1, wherein
the source gas instantaneously-heating mechanism includes a plurality of source gas instantaneously-heating mechanisms.

4. The heat beam film-forming apparatus according to claim 1, wherein
the source gas is water, a hydrogen carbide such as methane, an organic metal gas containing aluminum or one metal element selected from hafnium, gallium, zinc, titanium, silicon, magnesium, and indium, an inert gas containing nitrogen or argon, a reducing gas such as hydrogen or ammonia, or a gas mixture thereof.

5. The heat beam film-forming apparatus according to claim 1, wherein
a heating temperature of the source gas instantaneously-heating apparatus ranges from 100° C. to 900° C.

6. The heat beam film-forming apparatus according to claim 1, wherein
the substrate is glass, a silicon wafer, plastic, or carbon.

7. The heat beam film-forming apparatus according to claim 1, wherein the substrate moves.

8. The heat beam film-forming apparatus according to claim 1, wherein
the substrate is a substrate on which an organic EL device, a liquid crystal device, a solar battery cell, or a photoresist pattern is formed.
